(19) United States
(12) Patent Application Publication
(10) Pub. No.: US 2011/0234044 A1
(43) Pub. Date: Sep. 29, 2011

(54) PIEZOELECTRIC/ELECTROSTRICTIVE CERAMIC, MANUFACTURING METHOD FOR PIEZOELECTRIC/ELECTROSTRICTIVE CERAMIC, PIEZOELECTRIC/ ELECTROSTRICTIVE ELEMENT, AND MANUFACTURING METHOD FOR PIEZOELECTRIC/ELECTROSTRICTIVE ELEMENT

(75) Inventors: Yuji NOGUCHI, Meguro-Ku (JP); Masaru MIYAYAMA, Meguro-Ku (JP); Toshikatsu KASHIWAYA, Inazawa (JP); Takaaki KOIZUMI, Tajimi (JP); Shuichi OZAWA, Nagoya (JP); Ritsu TANAKA, Nagoya (JP)

(73) Assignees: NGK Insulators, Ltd., Nagoya (JP); The University of Tokyo, Bunkyo-Ku (JP)

(21) Appl. No.: 12/951,305

(22) Filed: Nov. 22, 2010

(30) Foreign Application Priority Data
Mar. 26, 2010 (JP) 2010-072378

(51) Int. Cl. H01L 41/04; H01L 41/187; H01L 41/22

(52) U.S. Cl. 310/311; 252/62.9 R; 252/62.9 PZ; 29/25.35

(57) ABSTRACT

Provided is a piezoelectric/electrostrictive ceramic which produces large electric-field induced strain without performing an aging treatment for a long period of time. A piezoelectric/electrostrictive ceramic sintered body in which the ratio of the number of ions at A sites to the number of ions at B sites in a perovskite structure is at least 0.94 to at most 0.99 is subjected to an oxygen heat treatment at a temperature of 600 to 1050° C. for 2 to 100 hours under an atmosphere with an oxygen partial pressure of 0.05 to 1.0 atm.

### BACKGROUND OF THE INVENTION

1. Field of the Invention

The present invention relates to a piezoelectric/electrostrictive ceramic and a technique associated with the same, and particularly to a bismuth sodium titanate based piezoelectric/electrostrictive ceramic and a technique associated with the same.

2. Description of the Background Art

Piezoelectric/electrostrictive actuators have an advantage that a displacement can be controlled precisely in a submicron order. In particular, piezoelectric/electrostrictive actuators using a piezoelectric/electrostrictive ceramic sintered body as a piezoelectric/electrostrictive body also have the advantages of its high electromechanical conversion efficiency, large generative force, high response speed, high durability, and low power consumption in addition to the ability to control displacement precisely. Therefore, the piezoelectric/electrostrictive actuators using a piezoelectric/electrostrictive ceramic sintered body as a piezoelectric/electrostrictive body are adopted for heads of inkjet printers, injectors of diesel engines, etc. by taking these advantages.

For the piezoelectric/electrostrictive ceramic sintered body for use in piezoelectric/electrostrictive actuators, lead zirconate titanate (hereinafter, referred to as “PZT”) based leaded piezoelectric/electrostrictive materials have been used conventionally. However, ever since an influence of lead from a sintered body on the global environment came to be strongly feared, the use of lead-free piezoelectric/electrostrictive materials such as bismuth sodium titanate (hereinafter, referred to as “BNT”) based materials has also been taken into consideration.

In BNT based lead-free piezoelectric/electrostrictive materials, an attempt to increase electric-field induced strain, which is important to piezoelectric/electrostrictive actuators has been made by solid-dissolving bismuth potassium titanate (hereinafter, referred to as “BKT”) or barium titanate (hereinafter, referred to as “BT”) in BNT. However, it is difficult to obtain large electric-field induced strain comparable to PZT based leaded piezoelectric/electrostrictive materials only by the above method.

Therefore, an attempt to obtain larger electric-field induced strain has been made by introducing defects into a crystal.

For example, Teranishi et al, “Giant-Strain Characteristics in (Bi_{0.5}Na_{0.5})TiO₃-based Ferroelectric Substance, Preliminary Manuscript of 46th Symposium on Basic Science of Ceramics, The Ceramic Society of Japan, Division of Basic Science, January 2008, pp. 482-483 discloses that large electric-field induced strain is obtained by introducing defects into a single crystal of BNT-BKT-BT, which is a solid solution of BNT, BKT, and BT.

In addition, Japanese Patent Application Laid-Open Nos. 2004-363557 and 2006-137654 disclose that large electric-field induced strain is obtained by substituting some of constituent elements with a donor or an acceptor and introducing defects having symmetry coincident with that of a crystal into a single crystal or a ceramic through an aging treatment for 5 days to 3 months.

Since growing temperatures of BNT-based single crystals are high temperatures of 1300° C. or more, it is difficult to control the concentrations of volatile components such as Bi (bismuth) and K (potassium) in the manufacture of BNT-based single crystals. Therefore, the BNT-based single crystals have a difference caused between the composition of a mixture of starting materials and the composition of a grown single crystal. This means that it is difficult to control the number of defects closely associated with the magnitude of electric-field induced strain.

In addition, single crystals have a problem that it is difficult to process the single crystals into the form of a film suitable for the piezoelectric/electrostrictive body for use in piezoelectric/electrostrictive actuators, because processing of single crystals is restricted.

In view of these issues, it is desirable to use a ceramic sintered body rather than the single crystal as described in Teranishi et al for the piezoelectric/electrostrictive body in piezoelectric/electrostrictive actuators. However, in piezoelectric/electrostrictive ceramic sintered bodies, a secondary phase is likely to be deposited at crystal grain boundaries. Thus, the findings concerning the single crystal, obtained from Teranishi et al are not able to be applied directly to piezoelectric/electrostrictive ceramics.

Accordingly, there is a need for findings concerning the introduction of defects into piezoelectric/electrostrictive ceramics. However, the introduction of defects into piezoelectric/electrostrictive ceramics according to the techniques disclosed in Japanese Patent Application Laid-Open Nos. 2004-363557 and 2006-137654 requires a long period of time for an aging treatment, and is thus not suitable for industrial production.

### SUMMARY OF THE INVENTION

The present invention is directed to a method for manufacturing a piezoelectric/electrostrictive ceramic.

According to a first aspect of the present invention, a piezoelectric/electrostrictive ceramic sintered body is subjected to an oxygen heat treatment at a temperature of 600 to 1050° C. for 2 to 100 hours under an atmosphere with an oxygen partial pressure of 0.05 to 1.0 atm. The ratio of the number of ions at A sites to the number of ions at B sites in a perovskite structure in the piezoelectric/electrostrictive ceramic is 0.94 or more and 0.99 or less.

A piezoelectric/electrostrictive ceramic which produces large electric-field induced strain can be provided without carrying out any aging treatment.

According to a second aspect of the present invention, a piezoelectric/electrostrictive ceramic sintered body is subjected to an oxygen heat treatment at a temperature of 600 to 1050° C. for 2 to 100 hours under an atmosphere with an oxygen partial pressure of 0.05 to 1.0 atm. The piezoelectric/electrostrictive ceramic sintered body contains a perovskite solid solution as its main constituent. The perovskite solid solution is represented by a general formula (Bi_{w}NaₓK_{y}Ba_{z})TiO_{2+(3w+x+y+2z)/2}, where w, x, y, and z satisfy the following conditional expressions: 0.35≦w≦0.53; 0.30≦x≦0.47; 0.00≦y≦0.12; 0.00≦z≦0.14; and 0.94≦w+x+y+z≦0.99, and at least one of y and z is not 0.

A piezoelectric/electrostrictive ceramic which produces large electric-field induced strain can be provided without carrying out any aging treatment.

The present invention is also directed to a piezoelectric/electrostrictive ceramic.

According to the third aspect of the present invention, a piezoelectric/electrostrictive ceramic is represented by a general formula (Bi_{w}NaₓK_{y}Ba_{z})TiO_{2+(3w+x+y+2z)/2}, where w, x, y, and z satisfy the following conditional expressions: 0.35≦w≦0.53; 0.30≦x≦0.47; 0.00≦y≦0.12; 0.00≦z≦0.14; and 0.94≦w+x+y+z≦0.99, and at least one of y and z is not 0.

A piezoelectric/electrostrictive ceramic which produces large electric-field induced strain can be provided without carrying out any aging treatment.

The present invention is also directed to a piezoelectric/electrostrictive element.

According to the forth aspect of the present invention, electrodes are opposed to each other with a piezoelectric/electrostrictive ceramic sintered body subjected to an oxygen heat treatment interposed therebetween. The piezoelectric/electrostrictive ceramic sintered body subjected to an oxygen heat treatment is manufactured by subjecting a piezoelectric/electrostrictive ceramic sintered body subjected to no oxygen heat treatment, to an oxygen heat treatment at a temperature of 600 to 1050° C. for 2 to 100 hours under an atmosphere with an oxygen partial pressure of 0.05 to 1.0 atm. The piezoelectric/electrostrictive ceramic sintered body subjected to no oxygen heat treatment contains a perovskite solid solution as its main constituent. The perovskite solid solution is represented by a general formula (Bi_{w}NaₓK_{y}Ba_{z})TiO_{2+(3w+x+y+2z)/2}, where w, x, y, and z satisfy the following conditional expressions: 0.35≦w≦0.53; 0.30≦x≦0.47; 0.00≦y≦0.12; 0.00≦z≦0.14; and 0.94≦w+x+y+z≦0.99, and at least one of y and z is not 0.

A piezoelectric/electrostrictive element which produces large displacement can be provided without carrying out any aging treatment.

The present invention is also directed to a method for manufacturing a piezoelectric/electrostrictive element.

According to the fifth aspect of the invention, a piezoelectric/electrostrictive ceramic sintered body subjected to no oxygen heat treatment is manufactured. The piezoelectric/electrostrictive ceramic sintered body subjected to no oxygen heat treatment contains a perovskite solid solution as its main constituent. The perovskite solid solution is represented by a general formula (Bi_{w}NaₓK_{y}Ba_{z})TiO_{2+(3w+x+y+2z)/2}, where w, x, y, and z satisfy the following conditional expressions: 0.35≦w≦0.53; 0.30≦x≦0.47; 0.00≦y≦0.12; 0.00≦z≦0.14; and 0.94≦w+x+y+z≦0.99, and at least one of y and z is not 0. The sintered body subjected to no oxygen is subjected to an oxygen heat treatment at a temperature of 600 to 1050° C. for 2 to 100 hours under an atmosphere with an oxygen partial pressure of 0.05 to 1.0 atm. Electrodes opposed to each other with the piezoelectric/electrostrictive ceramic sintered body interposed therebetween is manufactured.

A piezoelectric/electrostrictive element which produces large displacement can be provided without carrying out any aging treatment.

Therefore, a first object of the present invention is to provide a piezoelectric/electrostrictive ceramic which produces large electric-field induced strain without carrying out an aging treatment for a long period of time.

A second object of the present invention is to provide a piezoelectric/electrostrictive element which is superior in terms of reliability.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a flow diagram for explaining a flow of manufacture of a piezoelectric/electrostrictive ceramic according to a first preferred embodiment;

FIG. 2 is a sectional view of a piezoelectric/electrostrictive actuator according to a second preferred embodiment;

FIG. 3 is a sectional view of a piezoelectric/electrostrictive actuator according to a third preferred embodiment;

FIG. 4 is a sectional view of a piezoelectric/electrostrictive actuator according to a fourth preferred embodiment;

FIG. 5 is a perspective view of a piezoelectric/electrostrictive actuator according to a fifth preferred embodiment;

FIG. 6 is a longitudinal sectional view of the piezoelectric/electrostrictive actuator according to the fifth preferred embodiment;

FIG. 7 is a cross-sectional view of the piezoelectric/electrostrictive actuator according to the fifth preferred embodiment;

FIG. 8 is an exploded perspective view of a portion of the piezoelectric/electrostrictive actuator according to the fifth preferred embodiment;

FIG. 9 is a graph showing changes in polarization with respect to an electric field in the case of applying an alternating electric field to sample 7;

FIG. 10 is a graph showing changes in polarization with respect to an electric field in the case of applying an alternating electric field to sample 9;

FIG. 11 is a graph showing changes in strain with respect to an electric field in the case of applying an alternating electric field to sample 7; and

FIG. 12 is a graph showing changes in strain with respect to an electric field in the case of applying an alternating electric field to sample 9.

### DESCRIPTION OF THE PREFERRED EMBODIMENTS

### 1 First Preferred Embodiment

The first preferred embodiment relates to a piezoelectric/electrostrictive ceramic.

<1.1 Composition>

The piezoelectric/electrostrictive ceramic according to the first preferred embodiment has a composition represented by the general formula (Bi_{w}NaₓK_{y}Ba_{z})TiO_{2+(3w+x+y+2z)/2}, wherein w, x, y, and z satisfy the following conditional expressions:

0.35≦w≦0.53;

0.30≦x≦0.47;

0.00≦y≦0.12;

0.00≦z≦0.14; and

0.94≦w+x+y+z≦0.99, and

at least one of y and z is not 0.

The w, x, y, and z desirably further satisfy the following conditional expression:

w>x+y

The piezoelectric/electrostrictive ceramic according to the first preferred embodiment has a composition in which one or more of the A-site elements, Bi (bismuth), Na (sodium), K (potassium), and Ba (barium) are lacking with respect to the stoichiometry. The lack of the A-site elements with respect to the stoichiometry is 1 mol % or more and 6 mol % or less.

It is to be noted that the piezoelectric/electrostrictive ceramic according to the first preferred embodiment is allowed to contain a slight amount of impurities.

The BNT, BKT, and BT content rates x, y, and z are determined in the ranges mentioned above, because the electric-field induced strain develops a tendency to decrease when the content rates fall outside the ranges.

The lack of the A-site elements with respect to the stoichiometry is determined in the range mentioned above, because the electric-field induced strain develops a tendency to decrease when the lack falls below the range, and because the electric-field induced strain develops a tendency to decrease and the leakage current develops a tendency to increase when the lack exceeds the range.

<1.2 Crystal>

The piezoelectric/electrostrictive ceramic according to the first preferred embodiment includes BNT-BKT-BT, which is a solid solution of the BNT, BKT, and BT, and has a crystal structure of a perovskite structure. It is to be noted that the piezoelectric/electrostrictive ceramic according to the first preferred embodiment is allowed to contain a slight amount of secondary phase.

When the A-site elements are lacking with respect to the stoichiometry as described above, the A sites of the perovskite structure have holes caused. In addition, the amount of holes at the A sites is 1 mol % or more and 6 mol % or less.

<1.3 Domain Switching>

The holes caused at the A sites as described above make it easier to cause domain switching to contribute to causing large electric-field induced strain due to the rotation of the non-180° domain. When the rotation of the non-180° domain is likely to be caused, a jump phenomenon is observed in which the strain and polarization are nonlinearly rapidly increased in a certain electric field when an alternating electric field is applied.

<1.4 Manufacture>

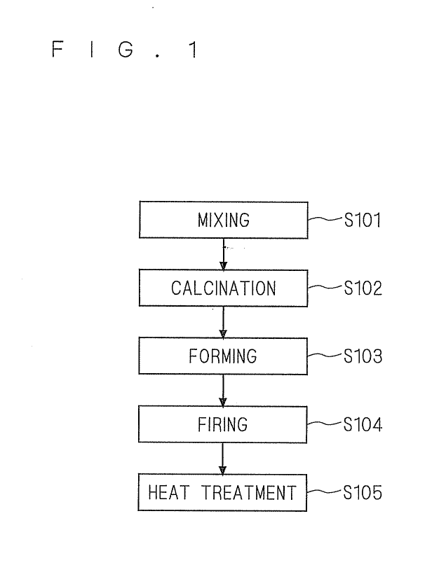

FIG. 1 is a flow diagram for explaining a flow of manufacture of a piezoelectric/electrostrictive ceramic according to the first preferred embodiment.

(a) Mixing (step S101):

First, starting materials for the constituent elements (Bi, Na, K, Ba, Ti) are mixed which are weighed so as to provide the composition described above. As the starting materials, compounds are used such as oxides or carbonates, tartrates, and oxalates to be finally converted to oxides. The mixing is carried out in a ball mill or the like. In the case of carrying out the mixing in a ball mill, an organic solvent such as ethanol, toluene, and acetone is used as a dispersion medium, and the removal of the dispersion medium from slurry is carried out by evaporative drying, filtration, centrifugation, or the like. Mixing may be performed by a dry method in place of a wet method.

(b) Calcination (step S102):

After mixing the starting materials, the mixed materials obtained are reacted by calcination. The calcination temperature is desirably 800 to 1000° C. In addition, the period for keeping the maximum temperature is desirably 2 to 10 hours.

In order to adjust the particle diameter and specific surface area, the obtained powder may be ground. In this case, the calcination and the grinding may be repeated twice or more. In addition, in order to adjust the particle diameter distribution, the obtained powder may be classified. Furthermore, in order to adjust the shapes and diameters of secondary particles, slurry of the obtained powder may be subjected to a granulation treatment such as spray drying.

(c) Forming (step S103):

After the calcination of the mixed materials, the obtained powder is formed. The forming is carried out by extrusion molding, injection molding, pressing, casting, tape casting, cold isostatic pressing (CIP) molding, or the like. After carrying out pressing, CIP molding may be further carried out. Prior to the molding, the powder may be mixed with a binder. In the case of mixing a binder, a polyvinyl butyral resin, a polyvinyl alcohol resin, a polyvinyl acetate resin, a polyacrylic resin, or the like is used as the binder.

(d) Firing (Step S104):

After forming the powder, the obtained compact is fired. The firing temperature is desirably 1100 to 1200° C. In addition, the period for keeping the maximum temperature is desirably 2 to 10 hours. When the powder is mixed with the resin binder, a heat treatment is desirably carried out for removing the resin binder from the compact.

(e) Heat Treatment (Step S105):

After the firing, the sintered body obtained is subjected to an oxygen heat treatment. The oxygen heat treatment is desirably carried out under an atmosphere with an oxygen partial pressure of 0.05 to 1.0 atm, and more desirably 0.11 to 0.60 atm. The temperature for carrying out the oxygen heat treatment is desirably 600 to 1050° C., and more desirably 700 to 1020° C. The period for carrying out the oxygen heat treatment is desirably 2 to 100 hours, and more desirably 4 to 60 hours. The period for carrying out the oxygen heat treatment is defined by the period for keeping the desirable temperature mentioned above.

After carrying out the oxygen heat treatment, processing such as cutting, grinding, and polishing may be applied to the sintered body, or after applying pressing such as cutting, grinding, and polishing to the sintered body, the oxygen heat treatment may be carried out. Prior to the firing, an electrode film may be formed on the surface of the compact, and the compact and the electrode film may be subjected to co-firing.

(f) Others

In the case of using the obtained sintered body for a piezoelectric/electrostrictive actuator and applying an electric field greater than the coercive electric field, it is not always necessary to apply a polarization treatment to the sintered body obtained. However, this does not interfere with the application of a polarization treatment to the sintered body obtained.

It is to be noted that it is not indispensable to react the starting materials for all of the constituent elements at once as described above, and the starting materials may be reacted twice or more in stages. For example, after synthesizing intermediates such as BNT, BKT, and BT, a solid solution BNT-BKT-BT may be synthesized by reacting the intermediates. Alternatively, a solid solution BNT-BKT-BT or intermediates may be synthesized in accordance with a method other than a solid phase reaction method, such as an alkoxide method.

<1.5 Applications>

The piezoelectric/electrostrictive ceramic sintered body according to the first preferred embodiment is preferably used for piezoelectric/electrostrictive actuators, because the application of a large electric field to the sintered body produces large electric-field induced strain. However, this does not interfere with the use of the piezoelectric/electrostrictive ceramic sintered body according to the first preferred embodiment for other piezoelectric/electrostrictive elements, for example, resonators, sensors, etc. Of course, in the case of using the piezoelectric/electrostrictive ceramic sintered body for resonators, sensors, etc and applying no electric field greater than the coercive electric field, the sintered body obtained is subjected to a polarization treatment.

### 2 Second Preferred Embodiment

The second preferred embodiment relates to a piezoelectric/electrostrictive actuator 402 using the piezoelectric/electrostrictive ceramic according to the first preferred embodiment.

<2.1 General Structure>

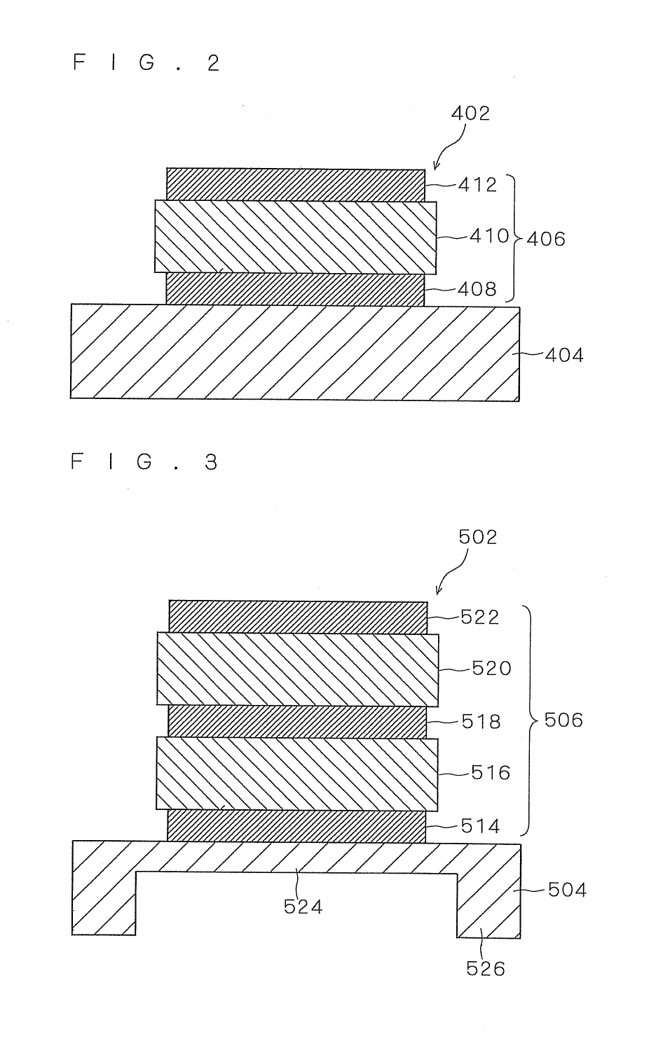

FIG. 2 is a schematic diagram of the piezoelectric/electrostrictive actuator 402 according to the second preferred embodiment. FIG. 2 is a sectional view of the single-layer type piezoelectric/electrostrictive actuator 402.

As shown in FIG. 2, the piezoelectric/electrostrictive actuator 402 has a structure of an electrode film 408, a piezoelectric/electrostrictive film 410, and an electrode film 412 stacked in this order on the upper surface of a substrate 404. The electrode films 408 and 412 on the both principal surfaces of the piezoelectric/electrostrictive film 410 are opposed to each other with the piezoelectric/electrostrictive film 410 interposed therebetween. The stacked body 406 including the electrode film 408, piezoelectric/electrostrictive film 410, and electrode film 412 stacked is solidly attached to the substrate 404.

The “being solidly attached” as used herein refers to bonding the stacked body 406 to the substrate 404 through a solid phase reaction at an interface between the substrate 404 and the stacked body 406 without the use of an organic adhesive agent or an inorganic adhesive agent.

In the case of the piezoelectric/electrostrictive actuator 402, when a voltage is applied, the piezoelectric/electrostrictive film 410 is expanded and contracted in a direction perpendicular to the electric field depending on the applied voltage, resulting in bending displacement caused.

<2.2 Piezoelectric/Electrostrictive Film 410>

The piezoelectric/electrostrictive film 410 is constructed with the use of the piezoelectric/electrostrictive ceramic sintered body according to the first preferred embodiment.

The piezoelectric/electrostrictive film 410 preferably has a film thickness of 0.5 to 50 μm, more preferably 0.8 to 40 μm, and particularly preferably 1 to 30 μm, because the piezoelectric/electrostrictive film 410 has a tendency to be insufficiently densified when the film thickness falls below this range, and because the increase in shrinkage stress during the sintering results in a need to increase the thickness of the substrate 404 and difficulty in reducing the size of the piezoelectric/electrostrictive actuator 402 when the film thickness exceeds this range.

<2.3 Electrode Films 408, 412>

The materials of the electrode films 408 and 412 are a metal such as platinum, palladium, rhodium, gold, and silver, or an alloy thereof. Above all, platinum or an alloy containing platinum as its main constituent is preferable in terms of high heat resistance against the firing. In addition, depending on the firing temperature, alloys such as silver-palladium can also be preferably used.

The electrode films 408 and 412 preferably have a film thickness of 15 μm or less, and more preferably 5 μm or less, because the electrode films 408 and 412 have a tendency to serve as relaxation layers to reduce bending displacement when the film thickness exceeds this range. In addition, in order for the electrode films 408 and 412 to play their roles appropriately, the film thickness is preferably 0.05 μm or more.

The electrode films 408 and 412 are preferably formed so as to cover a region which substantially contributes to bending displacement of the piezoelectric/electrostrictive film 410. For example, it is preferable to form the electrode films 408 and 412 so as to cover a region including a central portion of the piezoelectric/electrostrictive film 410 and 80% or more of the both principal surfaces of the piezoelectric/electrostrictive film 410.

<2.4 Substrate 404>

While the material of the substrate 404 is ceramic, the type of the material is not limited. However, in terms of heat resistance, chemical stability, and insulation, a ceramic is preferable which contains at least one selected from the group consisting of a stabilized zirconium oxide, an aluminum oxide, a magnesium oxide, mullite, an aluminum nitride, a silicon nitride, and glass. Above all, a stabilized zirconium oxide is more preferable in terms of mechanical strength and toughness. The “stabilized zirconium oxide” as used herein refers to a zirconium oxide with crystalline phase transition suppressed with the addition of a stabilizing agent, and encompasses partially stabilized zirconium oxides in addition to stabilized zirconium oxides.

The stabilized zirconium oxides can include, for example, zirconium oxides containing, as a stabilizing agent, 1 to 30 mol % of calcium oxide, magnesium oxide, yttrium oxide, ytterbium oxide, or cerium oxide, or oxide of rare-earth metal. Above all, zirconium oxides containing yttrium oxide as the stabilizing agent are preferable in terms of particularly high mechanical strength. The content of the yttrium oxide is preferably 1.5 to 6 mol %, and more preferably 2 to 4 mol %. It is more preferable to contain 0.1 to 5 mol % of aluminum oxide in addition to the yttrium oxide. While the crystalline phase of the stabilized zirconium oxide may include a mixed crystal of cubical crystal and monoclinic crystal, a mixed crystal of tetragonal crystal and monoclinic crystal, or a mixed crystal of cubical crystal, tetragonal crystal, and monoclinic crystal, the main crystalline phase is preferably a mixed crystal of tetragonal crystal and cubical crystal or a tetragonal crystal in terms of mechanical strength, toughness, and durability.

The substrate 404 preferably has a thickness of 1 to 1000 μm, more preferably 1.5 to 500 μm, and particularly preferably 2 to 200 μm, because the mechanical strength of the piezoelectric/electrostrictive actuator 402 has a tendency to decrease when the thickness falls below this range, and because when the thickness exceeds this ranges, the substrate 404 has a tendency to increase its rigidity, thereby resulting in reduction in bending displacement caused by expansion and contraction of the piezoelectric/electrostrictive film 410 in the case of applying a voltage.

The surface shape (the shape of the surface to which the stacked body 406 is solidly attached) of the substrate 404 is not particularly limited, may be triangle, quadrangle (rectangle or square), oval, or circular, and may have rounded corners in the case of a triangle or a quadrangle. The surface shape may be compositely shaped by combining these basic shapes.

<2.5 Manufacture of Piezoelectric/Electrostrictive Actuator 402>

For the manufacture of the piezoelectric/electrostrictive actuator 402, the electrode film 408 is first formed on the substrate 404. The electrode film 408 can be formed in accordance with a method such as ion beam, sputtering, vacuum deposition, PVD (Physical Vapor Deposition), ion plating, CVD (Chemical Vapor Deposition), plating, aerosol deposition, screen printing, spraying, and dipping. Above all, the sputtering method or the screen printing method is preferable in terms of bondability between the substrate 404 and the piezoelectric/electrostrictive film 410. The formed electrode film 408 can be solidly attached by a heat treatment to the substrate 404 and the piezoelectric/electrostrictive film 410.

Subsequently, the piezoelectric/electrostrictive film 410 is formed on the electrode film 408. The piezoelectric/electrostrictive film 410 can be formed in accordance with a method such as ion beam, sputtering, vacuum deposition, PVD, ion plating, CVD, plating, sol gel, aerosol deposition, screen printing, spraying, and dipping. Above all, the screen printing method is preferable in that piezoelectric/electrostrictive films can be continuously formed with a high degree of accuracy in planar shape and film thickness.

Further subsequently, the electrode film 412 is formed on the piezoelectric/electrostrictive film 410. The electrode film 412 can be formed in the same way as the electrode film 408.

Then, the substrate 404 with the stacked body 406 formed is subjected to firing in an integrated manner. This firing promotes sintering of the piezoelectric/electrostrictive film 410, and serves to thermally treat the electrode films 408 and 412.

The piezoelectric/electrostrictive film 410 is subjected to an oxygen heat treatment. If the furnace used for carrying out the oxygen heat treatment is a furnace which flows an oxygen atmosphere, a component in the piezoelectric/electrostrictive film may be evaporated to change the composition in some cases. Thus, the furnace is desirably a hermetically sealed furnace.

While the heat treatment of the electrode films 408 and 412 is preferably carried out at the same time as the firing in terms of productivity, this does not interfere with a heat treatment carried out for each formation of the electrode films 408 and 412. However, in the case of carrying out the firing of the piezoelectric/electrostrictive film 410 before the heat treatment of the electrode film 412, the electrode film 412 is subjected to a heat treatment at a temperature lower than the firing temperature of the piezoelectric/electrostrictive film 410. In the case of carrying out the firing of the piezoelectric/electrostrictive film 410 before the heat treatment of the electrode film 412, the oxygen heat treatment may be carried out before or after the heat treatment of the electrode film 412.

### 3 Third Preferred Embodiment

The third preferred embodiment relates to the structure of a piezoelectric/electrostrictive actuator 502 which can be adopted instead of the structure of the piezoelectric/electrostrictive actuator 402 according to the second preferred embodiment.

FIG. 3 is a schematic diagram of the piezoelectric/electrostrictive actuator 502 according to the third preferred embodiment. FIG. 3 is a sectional view of the multi-layer type piezoelectric/electrostrictive actuator 502.

As shown in FIG. 3, the piezoelectric/electrostrictive actuator 502 has a structure of an electrode film 514, a piezoelectric/electrostrictive film 516, an electrode film 518, a piezoelectric/electrostrictive film 520, and an electrode film 522 stacked in this order on the upper surface of a substrate 504. The electrode films 514 and 518 on the both principal surfaces of the piezoelectric/electrostrictive film 516 are opposed to each other with the piezoelectric/electrostrictive film 516 interposed therebetween, and the electrode films 518 and 522 on the both principal surfaces of the piezoelectric/electrostrictive film 520 are opposed to each other with the piezoelectric/electrostrictive film 520 interposed therebetween. The stacked body 506 of the electrode film 514, piezoelectric/electrostrictive film 516, electrode film 518, piezoelectric/electrostrictive film 520, and electrode film 522 stacked is solidly attached to the substrate 504. It is to be noted that while a case of using two piezoelectric/electrostrictive films is shown in FIG. 3, three or more piezoelectric/electrostrictive films may be used.

As for the thickness of the substrate 504 of the multi-layer type piezoelectric/electrostrictive actuator 502, a central portion 524 with the stacked body 506 bonded is made thinner than a peripheral portion 526. This is for increasing the bending displacement while keeping the mechanical strength of the substrate 504. It is to be noted the substrate 504 may be used instead of the substrate 404 in the single-layer type piezoelectric/electrostrictive actuator 402.

The multi-layer type piezoelectric/electrostrictive actuator 502 is also manufactured in the same way as the single-layer type piezoelectric/electrostrictive actuator 402, except that the numbers of piezoelectric/electrostrictive films and electrode films to be formed are increased.

### 4 Fourth Preferred Embodiment

The fourth preferred embodiment relates to the structure of a piezoelectric/electrostrictive actuator 602 which can be adopted instead of the structure of the piezoelectric/electrostrictive actuator 402 according to the second preferred embodiment.

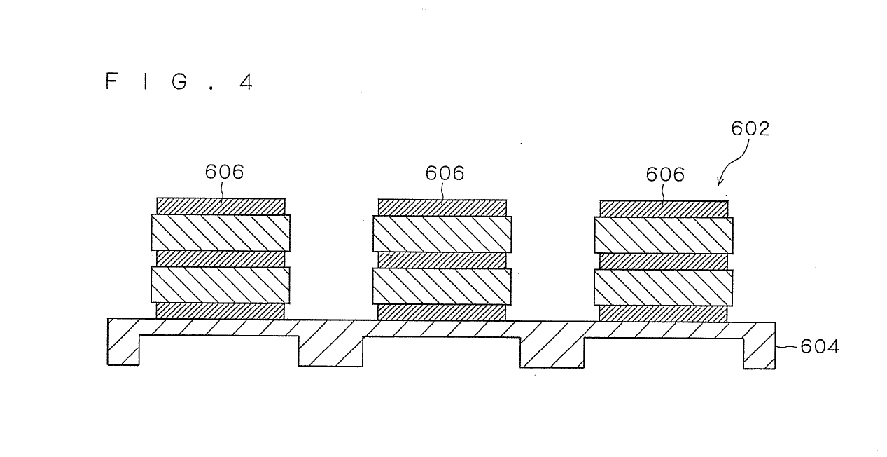

FIG. 4 is a schematic diagram of the piezoelectric/electrostrictive actuator 602 according to the fourth preferred embodiment. FIG. 4 is a sectional view of the multi-layer type piezoelectric/electrostrictive actuator 602.

As shown in FIG. 4, the piezoelectric/electrostrictive actuator 602 includes a substrate 604 formed of unit structures repeated with the substrate 504 shown in FIG. 3 as a unit structure, and stacked bodies 606 solidly attached onto the unit structures. Each of the stacked bodies 606 is the same as the stacked body 506 according to the third preferred embodiment.

The piezoelectric/electrostrictive actuator 602 is also manufactured in the same way as the piezoelectric/electrostrictive actuator 402, except that the numbers of piezoelectric/electrostrictive films and electrode films to be formed are increased and the number of stacked bodies is increased.

### 5 Fifth Preferred Embodiment

The fifth preferred embodiment relates to a piezoelectric/electrostrictive actuator 702 using the piezoelectric/electrostrictive ceramic sintered body according to the first preferred embodiment.

<5.1 General Structure>

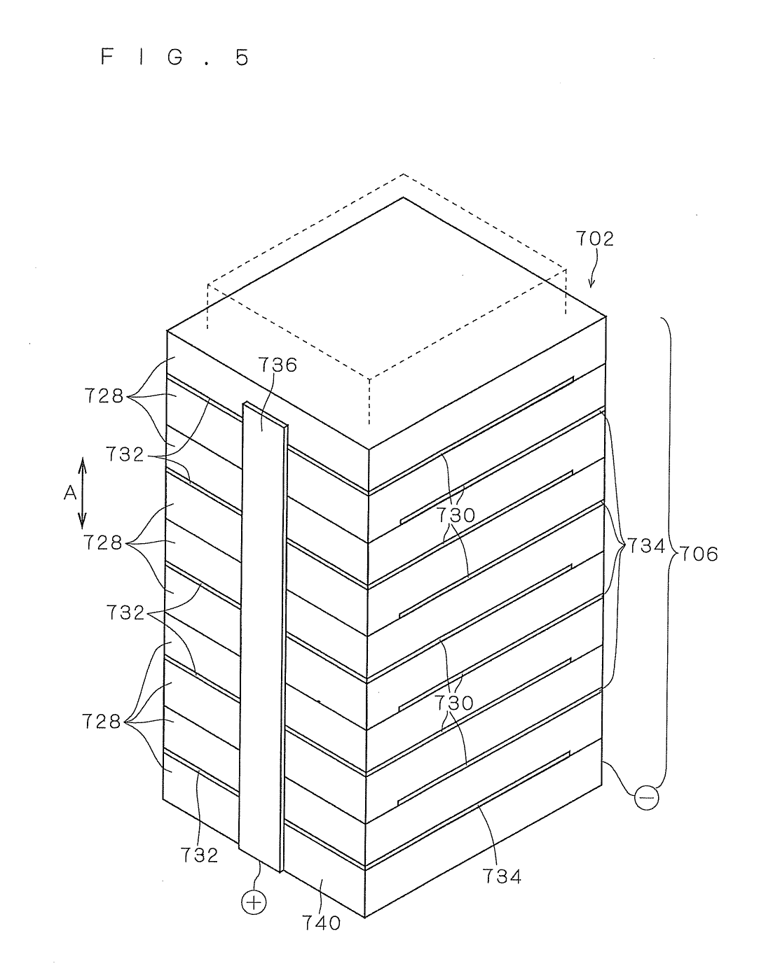

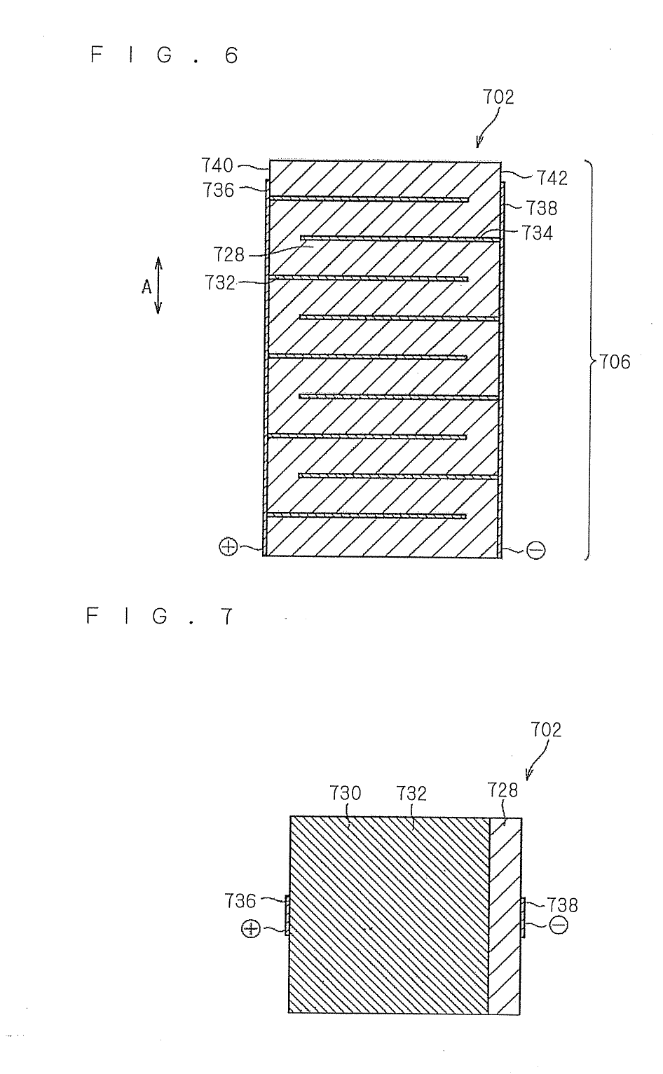

FIGS. 5 to 7 are schematic diagrams of the piezoelectric/electrostrictive actuator 702. FIG. 5 is a perspective view of the piezoelectric/electrostrictive actuator 702, FIG. 6 is a longitudinal sectional view of the piezoelectric/electrostrictive actuator 702, and FIG. 7 is a cross-sectional view of the piezoelectric/electrostrictive actuator 702.

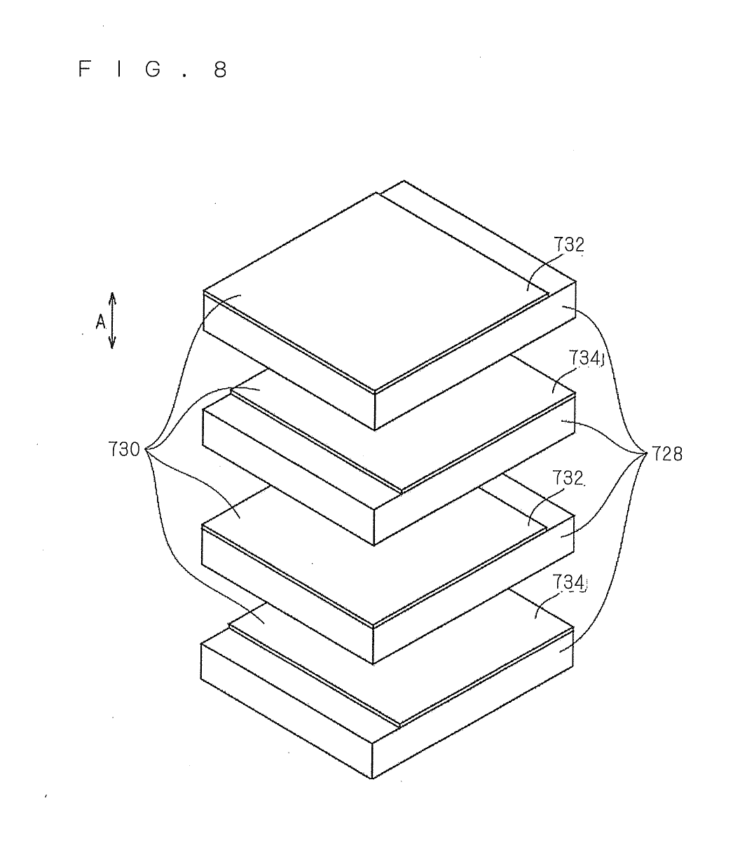

As shown in FIGS. 5 to 7, the piezoelectric/electrostrictive actuator 702 has a structure of piezoelectric/electrostrictive films 728 and internal electrode films 730 stacked alternately in the direction of an axis A and external electrode films 736 and 738 formed respectively on end surfaces 740 and 742 of the stacked body 706 including the piezoelectric/electrostrictive films 728 and internal electrode films 730 stacked. As shown in an exploded perspective view of FIG. 8 which shows a portion of the piezoelectric/electrostrictive actuator 702 exploded in the direction of the axis A, the internal electrode films 730 include first internal electrode films 732 reaching the end surface 740 but not the end surface 742 and second internal electrode films 734 reaching the end surface 742 but not the end surface 740. The first internal electrode films 732 and the second internal electrode films 734 are alternately provided. The first internal electrode films 732 are brought into contact with the external electrode film 736 to be electrically connected to the external electrode film 736 at the end surface 740. The second internal electrode films 734 are brought into contact with the external electrode film 738 to be electrically connected to the external electrode film 738 at the end surface 742. Therefore, when the external electrode film 736 and the external electrode film 738 are connected respectively to the plus and minus of a driving signal source, a driving signal is applied to the first internal electrode films 732 and second internal electrode films 734 opposed with the piezoelectric/electrostrictive films 728 interposed therebetween, so that an electric field is applied in the thickness direction of the piezoelectric/electrostrictive films 728. As a result, the piezoelectric/electrostrictive films 728 are expanded and contracted in the thickness direction, and the stacked body 706 is thus deformed as a whole into the shape indicated by a dashed line in FIG. 5.

The piezoelectric/electrostrictive actuator 702 includes no substrate to which the stacked body 706 is solidly attached, unlike the already described piezoelectric/electrostrictive actuators 402, 502, and 602. In addition, the piezoelectric/electrostrictive actuator 702 is also referred to as an “offset-type piezoelectric/electrostrictive actuator”, since the first internal electrode films 732 and the second internal electrode films 734, which differ in pattern, are alternately provided.

<5.2 Piezoelectric/Electrostrictive Films 728>

The piezoelectric/electrostrictive films 728 are constructed with the use of the piezoelectric/electrostrictive ceramic sintered body according to the first preferred embodiment. The piezoelectric/electrostrictive films 728 preferably have a film thickness of 5 to 500 μm, because it will be difficult to manufacture green sheets as will be described later when the film thickness falls below this range, and because it will be difficult to apply a sufficient electric field to the piezoelectric/electrostrictive films 728 when the film thickness exceeds this range.

<5.3 Internal Electrode Films 730 and External Electrode Films 736, 738>

The materials of the internal electrode films 730 and external electrode films 736 and 738 are a metal such as platinum, palladium, rhodium, gold, or silver, or an alloy thereof. Above all, for the material of the internal electrode films 730, platinum or an alloy containing platinum as its main constituent is preferable in terms of high heat resistance against the firing and easy co-sintering in combination with the piezoelectric/electrostrictive films 728. However, depending on the firing temperature, alloys such as silver-palladium can also be preferably used.

The internal electrode films 730 preferably have a film thickness of 10 μm or less, because the internal electrode films 730 have a tendency to serve as relaxation layers to reduce displacement when the film thickness exceeds this range. In addition, in order for the internal electrode films 730 to play their roles appropriately, the film thickness is preferably 0.1 μm or more.

While FIGS. 5 to 7 show a case in which the number of piezoelectric/electrostrictive films 728 is 10, the number of piezoelectric/electrostrictive films 728 may be 9 or less or 11 or more.

<5.4 Manufacture of Piezoelectric/Electrostrictive Actuator 702>

For the manufacture of the piezoelectric/electrostrictive actuator 702, first, a piezoelectric/electrostrictive ceramic powder with a binder, a plasticizer, a dispersant, and a dispersion medium added thereto is mixed in a ball mill or the like. Then, the obtained slurry is formed into the shape of a sheet in accordance with a doctor blade method or the like to obtain green sheets.

Subsequently, a punch or a die is used to apply punching to the green sheets, thereby forming holes for alignment in the green sheets.

Further subsequently, an electrode paste is applied by screen printing or the like onto the surfaces of the green sheets to obtain green sheets with electrode paste patterns formed. The electrode paste patterns include two types: first electrode paste patterns to serve as the first internal electrode films 732 after the firing and second electrode paste patterns to serve as the second internal electrode films 734 after the firing. Of course, the orientations of the green sheets may be rotated by 180° every other green sheet with the use of only one type of electrode paste pattern in such a way that the internal electrode films 732 and 734 are obtained after the firing.

Next, the green sheets with the first electrode paste patterns formed and the green sheets with the second electrode paste patterns formed are stacked alternately, the green sheet with no electrode paste applied is further stacked on the top, and the stacked green sheets are then subjected to pressure bonding under pressure in the thickness direction. In this case, an adjustment is made so that the holes for alignment formed in the green sheets are located in the same position. For pressure bonding of the stacked green sheets, the green sheets are also desirably subjected to pressure bonding while heating the green sheets with the use of a mold heated for use in the pressure bonding.

The thus obtained body of the green sheets subjected to pressure bonding is subjected to firing, and to an oxygen heat treatment, and the obtained sintered body is processed with the use of dicing saw or the like, thereby providing the stacked body 706. The oxygen heat treatment may be carried out after processing the obtained sintered body with the use of dicing saw or the like. Then, the external electrode films 736 and 738 are formed on the end surfaces 740 and 742 of the stacked body 706 by firing, vapor deposition, sputtering, or the like.

### EXAMPLE

The results of manufacture and evaluation of samples 1 to 30 will be described below.

<1 Manufacture of Samples 1 to 30>

For the manufacture of samples 1 to 30, Bi₂O₃ (bismuth oxide), TiO₂ (titanium oxide), Na₂CO₃ (sodium carbonate), K₂CO₃ (potassium carbonate), and BaCO₃ (barium carbonate) as starting materials were weighed to provide the compositions shown in Table 1, Table 2, and Table 3. The compositions of samples 1 to 30 are represented by the general formula (Bi_{w}NaₓK_{y}Ba_{z})TiO_{2+(3w+x+y+2z)/2}, where w, x, y, and z correspond to the compositions shown in the columns “w”, “x”, “y”, and “z” of Table 1, Table 2, and Table 3.

TABLE 1

| | | | | | | Electric-Field | | Leakage Current after |
|---|---|---|---|---|---|---|---|---|
| | | | | | | Induced Strain | Leakage Current | Continuous Driving |
| Sample | w | x | y | z | w + x + y + z | (%) | (A/cm²) | (A/cm²) |
| 1 | 0.45 | 0.38 | 0.06 | 0.07 | 0.96 | 0.23 | 10⁻⁸ to 10⁻⁷ | 10⁻⁸ to 10⁻⁷ |
| 2* | 0.33 | 0.47 | 0.07 | 0.09 | 0.96 | 0.05 | 10⁻⁷ to 10⁻⁶ | 10⁻⁷ to 10⁻⁶ |
| 3 | 0.35 | 0.45. | 0.07 | 0.08 | 0.95 | 0.18 | 10⁻⁸ to 10⁻⁷ | 10⁻⁸ to 10⁻⁷ |
| 4 | 0.40 | 0.42 | 0.07 | 0.08 | 0.97 | 0.20 | 10⁻⁸ to 10⁻⁷ | 10⁻⁸ to 10⁻⁷ |
| 5 | 0.53 | 0.32 | 0.05 | 0.06 | 0.96 | 0.19 | 10⁻⁸ to 10⁻⁷ | 10⁻⁸ to 10⁻⁷ |
| 6* | 0.55 | 0.31 | 0.05 | 0.06 | 0.97 | 0.09 | 10⁻⁸ to 10⁻⁷ | 10⁻⁷ to 10⁻⁶ |
| 7* | 0.53 | 0.28 | 0.07 | 0.08 | 0.96 | 0.11 | 10⁻⁸ to 10⁻⁷ | 10⁻⁷ to 10⁻⁶ |
| 8 | 0.51 | 0.30 | 0.07 | 0.08 | 0.96 | 0.18 | 10⁻⁸ to 10⁻⁷ | 10⁻⁸ to 10⁻⁷ |
| 9 | 0.42 | 0.42 | 0.06 | 0.07 | 0.97 | 0.20 | 10⁻⁸ to 10⁻⁷ | 10⁻⁸ to 10⁻⁷ |
| 10 | 0.38 | 0.47 | 0.05 | 0.06 | 0.96 | 0.18 | 10⁻⁸ to 10⁻⁷ | 10⁻⁸ to 10⁻⁷ |
| 11* | 0.36 | 0.49 | 0.05 | 0.06 | 0.96 | 0.13 | 10⁻⁷ to 10⁻⁶ | 10⁻⁷ to 10⁻⁶ |
| 12 | 0.48 | 0.41 | 0.00 | 0.07 | 0.96 | 0.18 | 10⁻⁸ to 10⁻⁷ | 10⁻⁸ to 10⁻⁷ |
| 13 | 0.38 | 0.32 | 0.20 | 0.07 | 0.96 | 0.19 | 10⁻⁸ to 10⁻⁷ | 10⁻⁸ to 10⁻⁷ |
| 14* | 0.37 | 0.31 | 0.22 | 0.06 | 0.96 | 0.13 | 10⁻⁷ to 10⁻⁶ | 10⁻³ to 10⁻² |
| 15 | 0.49 | 0.41 | 0.06 | 0.00 | 0.96 | 0.19 | 10⁻⁸ to 10⁻⁷ | 10⁻⁸ to 10⁻⁷ |
| 16 | 0.41 | 0.35 | 0.06 | 0.14 | 0.96 | 0.18 | 10⁻⁸ to 10⁻⁷ | 10⁻⁸ to 10⁻⁷ |
| 17* | 0.40 | 0.34 | 0.05 | 0.16 | 0.96 | 0.09 | 10⁻⁷ to 10⁻⁶ | 10⁻⁵ to 10⁻⁴ |

TABLE 2

| | | | | | | Electric-Field | | Leakage Current after |
|---|---|---|---|---|---|---|---|---|
| | | | | | | Induced Strain | Leakage Current | Continuous Driving |
| Sample | w | x | y | z | w + x + y + z | (%) | (A/cm²) | (A/cm²) |
| 18* | 0.43 | 0.36 | 0.06 | 0.07 | 0.92 | 0.18 | 10⁻⁷ to 10⁻⁶ | 10⁻³ to 10⁻² |
| 19 | 0.44 | 0.37 | 0.06 | 0.07 | 0.94 | 0.21 | 10⁻⁸ to 10⁻⁷ | 10⁻⁸ to 10⁻⁷ |
| 20 | 0.46 | 0.39 | 0.06 | 0.07 | 0.98 | 0.20 | 10⁻⁸ to 10⁻⁷ | 10⁻⁸ to 10⁻⁷ |
| 21* | 0.47 | 0.40 | 0.05 | 0.07 | 1.00 | 0.11 | 10⁻⁸ to 10⁻⁷ | 10⁻⁷ to 10⁻⁶ |

TABLE 3

| | | | | | | Oxygen | | | |
|---|---|---|---|---|---|---|---|---|---|
| | | | | | | Partial | Electric-Field | Leakage | Leakage Current |
| | | | | | | Pressure | Induced Strain | Current | after Continuous |
| Sample | w | x | y | z | w + x + y + z | (atm) | (%) | (A/cm²) | Driving (A/cm²) |
| 22 | 0.49 | 0.34 | 0.06 | 0.06 | 0.95 | 0.0002 | 0.01 | 10⁻⁷ to 10⁻⁶ | 10⁻³ to 10⁻² |
| 23 | 0.49 | 0.34 | 0.06 | 0.06 | 0.95 | 0.002 | 0.05 | 10⁻⁷ to 10⁻⁶ | 10⁻⁵ to 10⁻⁴ |
| 24 | 0.49 | 0.34 | 0.06 | 0.06 | 0.95 | 0.02 | 0.07 | 10⁻⁷ to 10⁻⁶ | 10⁻⁷ to 10⁻⁶ |
| 25 | 0.49 | 0.34 | 0.06 | 0.06 | 0.95 | 0.05 | 0.20 | 10⁻⁸ to 10⁻⁷ | 10⁻⁸ to 10⁻⁷ |
| 26 | 0.49 | 0.34 | 0.06 | 0.06 | 0.95 | 0.2 | 0.24 | 10⁻⁸ to 10⁻⁷ | 10⁻⁸ to 10⁻⁷ |
| 27 | 0.49 | 0.34 | 0.06 | 0.06 | 0.95 | 0.4 | 0.22 | 10⁻⁸ to 10⁻⁷ | 10⁻⁸ to 10⁻⁷ |
| 28 | 0.49 | 0.34 | 0.06 | 0.06 | 0.95 | 1 | 0.19 | 10⁻⁸ to 10⁻⁷ | 10⁻⁸ to 10⁻⁷ |
| 29 | 0.49 | 0.34 | 0.06 | 0.06 | 0.95 | 2 | 0.03 | 10⁻⁸ to 10⁻⁷ | 10⁻⁸ to 10⁻⁷ |
| 30 | 0.49 | 0.34 | 0.06 | 0.06 | 0.95 | 10 | 0.02 | 10⁻⁸ to 10⁻⁷ | 10⁻⁸ to 10⁻⁷ |

After weighing the starting materials, the weighed starting materials, ethanol as a dispersion medium, and silicon nitride balls as grinding media were enclosed within a wide-mouth bottle, and the starting materials were mixed and ground with the use of a planetary ball mill for 1 hour. In addition, after the completion of mixing and grinding, the ethanol was removed from the slurry by evaporative drying.

Subsequently, the mixed materials were subjected to calcination at 1000° C. The period for keeping the maximum temperature was set to 4 hours.

Further subsequently, the calcined materials, ethanol as a dispersion medium, and silicon nitride balls as grinding media were enclosed within a wide-mouth bottle, and the calcined materials were ground with the use of a planetary ball mill for 1 hour.

Next, the powder was placed in a cylindrical hole 10 mm in diameter formed in a mold of a molding machine, and subjected to uniaxial pressing at a pressure of 15 MPa. Furthermore, the compact was subjected to CIP molding at a pressure of 100 MPa.

Subsequently, the compact was subjected to firing at 1170° C. Then, the obtained sintered body was put in an electric furnace which is capable of controlling the oxygen partial pressure, and subjected to an oxygen heat treatment at 950° C. for 10 hours under an atmosphere with an oxygen partial pressure of 0.2 atm for samples 1 to 21 and under an atmosphere with the oxygen partial pressure shown in Table 3 for samples 22 to 30. The period for keeping the maximum temperature was set to 4 hours. The thus obtained sintered body was sliced with the use of a step cutter to be pressed into a disc shape with a thickness of 200 μm.

Finally, a gold electrode film with a thickness of 100 nm was formed by sputtering onto the both surfaces of the disc-shaped sintered body. The planar shape of the gold electrode film was circular, and had a diameter of 1 mm.

<2 Evaluation of Samples 1 to 21>

Subsequently, the electric-field induced strain, leakage current, and leakage current after continuous driving were measured for samples 1 to 21. The results are shown in Table 1 and Table 2. The electric-field induced strain was measured with the use of ferroelectric evaluation system 6252 Rev.B manufactured by TOYO Corporation. The electric-field induced strain refers to a ratio of expansion in the thickness direction in the case of applying an alternating electric field in the thickness direction of the disc-shaped sintered body. The applied alternating electric field had the amplitude of 10 kV/mm and a frequency of 0.5 Hz. The leakage current refers to a value in the case of relaxation time of 30 seconds. The leakage current after continuous driving refers to a leakage current value after continuously applying an alternating electric field of 5 kV/mm at a frequency of 0.5 Hz for 168 hours.

As shown in Table 1, in the case of samples 1 to 21 for which w, x, y, and z were varied while the total value of w+x+y+z was set to 0.94 to 0.99, large electric-field induced strain was obtained for the samples in which the w, x, y, and z fall within the ranges mentioned above. However, only small electric-field induced strain was obtained for the samples in which the w, x, y, and z fall outside the ranges mentioned above. In addition, for samples 2, 6, 7, 11, 14, and 17, the leakage current developed an increasing tendency.

As shown in Table 2, when the total value of w+x+y+z was varied, large electric-field induced strain was obtained without developing a tendency of the leakage current to increase for sample 19 with the total value of 0.94 and sample 20 with the total value of 0.98. On the other hand, a tendency of the leakage current to increase and a tendency of the leakage current after the continuous driving to increase significantly were developed for sample 18 with the total value of 0.92. In addition, for sample 21 with the total value of 1.00, only small electric-field induced strain was obtained, and the leakage current after the continuous driving developed an increasing tendency. The existence of a secondary phase identified as Bi₄Ti₃O₁₂ has been made clear from an X-ray diffraction analysis of the sintered body of sample 21.

As shown in Table 3, for samples 25 to 28 for which the oxygen partial pressure was varied within the range of 0.05 to 1 atm, large electric-field induced strain was obtained without developing a tendency of the leakage current or the leakage current after the continuous driving to increase. However, for samples 22 to 24 with the oxygen partial pressure less than 0.05 atm, only small electric-field induced strain was obtained, and the leakage current and the leakage current after the continuous driving developed increasing tendencies. In addition, for samples 29 and 30 with the oxygen partial pressure greater than 1 atm, only small electric-field induced strain was obtained.

The compositions are quantified by ICP (inductively-coupled plasma) emission spectrometry. The contents of Bi and Ti are quantified more precisely through the use of a wet chemical analysis method such as a gravimetric method or a titration method.

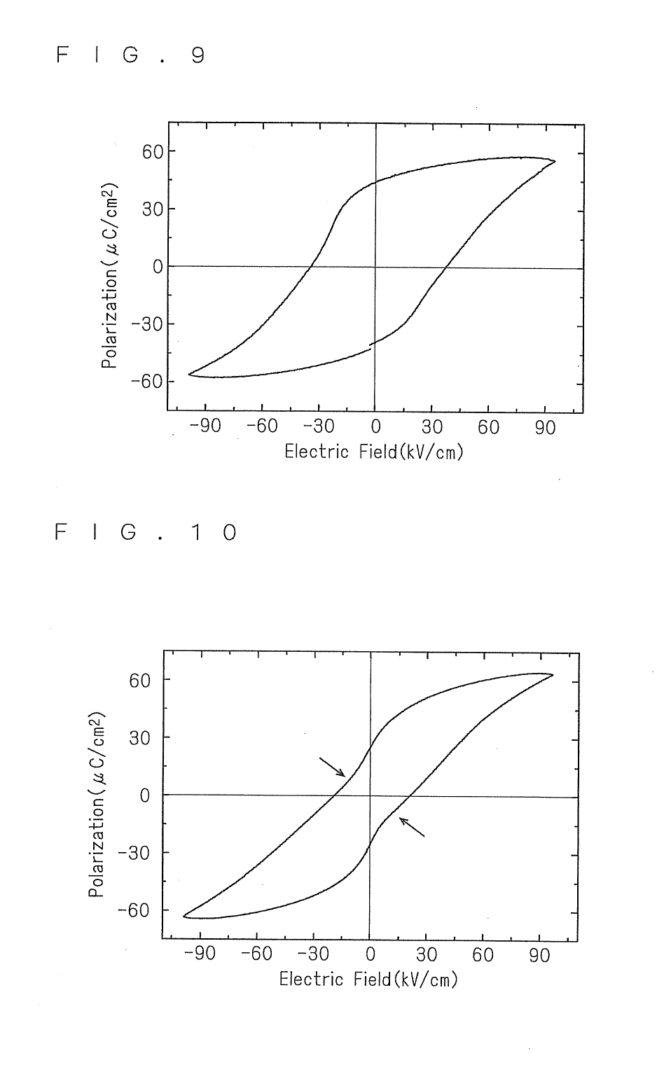

FIGS. 9 and 10 are graphs showing changes in polarization with respect to an electric field respectively in the case of applying an alternating electric field to samples 7 and 9. As is clear from a comparison of FIG. 9 with FIG. 10, for sample 9, a hysteresis loop similar to an antiferroelectric substance was observed in which the polarization is rapidly changed around arrows.

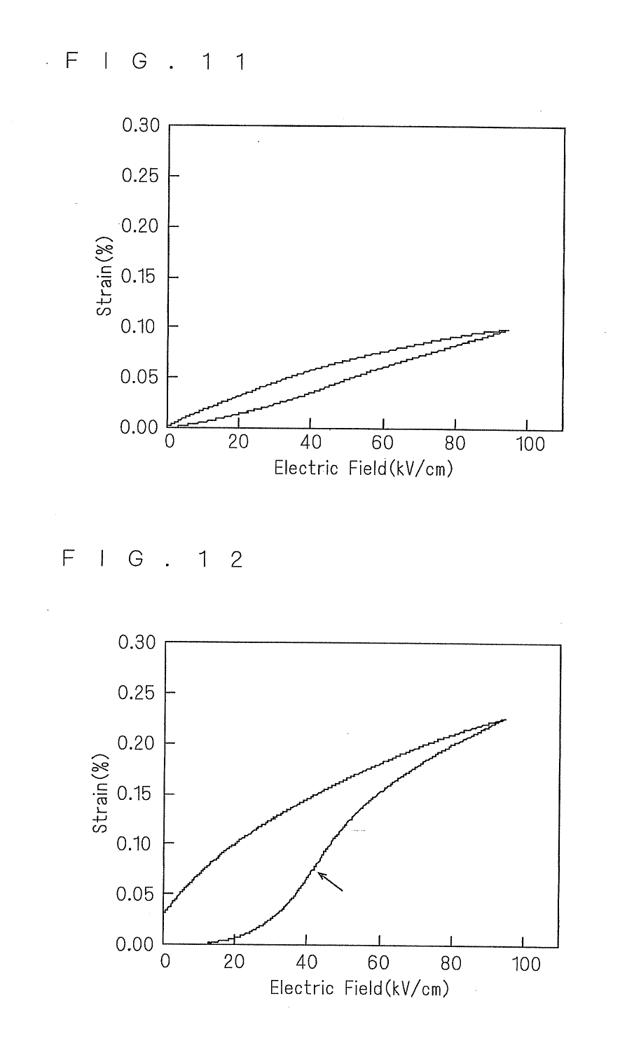

FIGS. 11 and 12 are graphs showing changes in strain with respect to an electric field respectively in the case of applying an alternating electric field to samples 7 and 9. As is clear from a comparison of FIG. 11 with FIG. 12, the strain is rapidly changed around an arrow for sample 9.

While the present invention has been shown and described in detail, the foregoing description is in all aspects illustrative and not restrictive. It is therefore understood that numerous modifications and variations, which have not been illustrated, can be devised without departing from the scope of the present invention.

What is claimed is:

1. A method for manufacturing a piezoelectric/electrostrictive ceramic, wherein a piezoelectric/electrostrictive ceramic sintered body in which a ratio of the number of ions at A sites to the number of ions at B sites in a perovskite structure is at least 0.94 to at most 0.99 is subjected to an oxygen heat treatment at a temperature of 600 to 1050° C. for 2 to 100 hours under an atmosphere with an oxygen partial pressure of 0.05 to 1.0 atm.

2. The method for manufacturing a piezoelectric/electrostrictive ceramic according to claim 1, wherein a piezoelectric/electrostrictive ceramic sintered body containing no lead is subjected to said oxygen heat treatment.

3. A piezoelectric/electrostrictive ceramic represented by a general formula (Bi_{w}NaₓK_{y}Ba_{z})TiO_{2+(3w+x+y+2z)/2}, where w, x, y, and z satisfy the following conditional expressions:
0.35≦w≦0.53;
0.30≦x≦0.47;
0.00≦y≦0.12;
0.00≦z≦0.14; and
0.94≦w+x+y+z≦0.99, and
at least one of y and z is not 0.

4. The piezoelectric/electrostrictive ceramic according to claim 3, wherein w, x, y, and z further satisfy the following conditional expression:
w>x+y.

5. A method for manufacturing a piezoelectric/electrostrictive ceramic, wherein a piezoelectric/electrostrictive ceramic sintered body containing a perovskite solid solution as its main constituent is subjected to an oxygen heat treatment at a temperature of 600 to 1050° C. for 2 to 100 hours under an atmosphere with an oxygen partial pressure of 0.05 to 1.0 atm, said perovskite solid solution being represented by a general formula (Bi_{w}NaₓK_{y}Ba_{z})TiO_{2+(3w+x+y+2z)/2}, where w, x, y, and z satisfy the following conditional expressions:
0.35≦w≦0.53;
0.30≦x≦0.47;
0.00≦y≦0.12;
0.00≦z≦0.14; and
0.94≦w+x+y+z≦0.99, and
at least one of y and z is not 0.

6. The method for manufacturing a piezoelectric/electrostrictive ceramic according to claim 5, wherein w, x, y, and z further satisfy the following conditional expression:
w>x+y.

7. A piezoelectric/electrostrictive element comprising:
a piezoelectric/electrostrictive ceramic sintered body subjected to an oxygen heat treatment; and
electrodes opposed to each other with said sintered body interposed therebetween,
wherein said sintered body subjected to the oxygen heat treatment is manufactured by subjecting a piezoelectric/electrostrictive ceramic sintered body subjected to no oxygen heat treatment, to an oxygen heat treatment at a temperature of 600 to 1050° C. for 2 to 100 hours under an atmosphere with an oxygen partial pressure of 0.05 to 1.0 atm, the piezoelectric/electrostrictive ceramic sintered body containing a perovskite solid solution represented by a general formula (Bi_{w}NaxK_{y}Ba_{z})TiO_{2+(3w+x+y+2z)/2}, where w, x, y, and z satisfy the following conditional expressions:
0.35≦w≦0.53;
0.30≦x≦0.47;
0.00≦y≦0.12;
0.00≦z≦0.14; and
0.94<w+x+y+z≦0.99, and
at least one of y and z is not 0 as its main constituent.

8. The piezoelectric/electrostrictive element according to claim 7, wherein w, x, y, and z further satisfy the following conditional expression:
w>x+y.

9. A method for manufacturing a piezoelectric/electrostrictive element, the method comprising the steps of:
a) manufacturing a piezoelectric/electrostrictive ceramic sintered body subjected to no oxygen heat treatment, the piezoelectric/electrostrictive ceramic sintered body containing a perovskite solid solution represented by a general formula (Bi_{w}NaₓK_{y}Ba_{z})TiO_{2+(3w+x}_{+y+2z)/2}, where w, x, y, and z satisfy the following conditional expressions:
0.35≦w≦0.53;
0.30≦x≦0.47;
0.00≦y≦0.12;
0.00≦z≦0.14; and
0.94≦w+x+y+z≦0.99, and
at least one of y and z is not 0 as its main constituent;
b) subjecting said sintered body subjected to no oxygen heat treatment, to an oxygen heat treatment at a temperature of 600 to 1050° C. for 2 to 100 hours under an atmosphere with an oxygen partial pressure of 0.05 to 1.0 atm; and
c) manufacturing electrodes opposed to each other with the sintered body interposed therebetween.

10. The method for manufacturing a piezoelectric/electrostrictive element according to claim 9, wherein w, x, y, and z further satisfy the following conditional expression:
w>x+y.
